(19) United States
(12) Patent Application Publication
(10) Pub. No.: US 2006/0002501 A1
(43) Pub. Date: Jan. 5, 2006

(54) Ultra-fast hopping frequency synthesizer for multi-band transmission standards

(75) Inventor: Markus Muller, Bochum (DE)

Correspondence Address: FOLEY & LARDNER LLP, 321 NORTH CLARK STREET, SUITE 2800, CHICAGO, IL, 60610-4764, US

(73) Assignee: Nokia Corporation

(21) Appl. No.: 10/882,983

(22) Filed: Jun. 30, 2004

(51) Int. Cl. H04L 7/00; H03B 21/00

(52) U.S. Cl. 375/371; 327/105

(57) ABSTRACT

A system, device, computer program product, and method provide fast frequency hopping. The system includes a terminal and a base station in communication with the terminal to receive an output signal. The terminal includes a communication interface, a processor, and a frequency synthesizer. The processor couples to the communication interface and selects the transmission center frequency of the output signal from a plurality of center frequencies capable of transmission from the communication interface. The frequency synthesizer includes a frequency controller, a multi-band oscillator, and a frequency calibrator. The frequency controller controls a center frequency for the plurality of center frequencies and selects the center frequency corresponding to the selected transmission center frequency. The multi-band oscillator generates a local oscillator signal having the selected center frequency. The frequency calibrator defines a correction value for the center frequency of the local oscillator signal and sends the correction value to the frequency controller.

### FIELD OF THE INVENTION

The present invention is related to wireless data transmission. More particularly, the present invention relates to frequency generation and synthesis in radio frequency wireless data transmission systems.

### BACKGROUND OF THE INVENTION

The Multi-Band Orthogonal Frequency Division Multiplexing (OFDM) Alliance (MBOA) supports the development of the best technical solution for the emerging Ultra Wideband (IEEE 802.15.3a) PHY specification for a diverse set of wireless applications. Existing wireless technologies such as WiFi and Bluetooth serve similar functions, but cannot handle large files like digital video. OFDM has been adopted for several technologies: Asymmetric Digital Subscriber Line services, IEEE 802.11a/g, IEEE 802.16a, Digital Audio Broadcast, and Digital Terrestrial Television Broadcast in Europe and in Japan. OFDM is being considered for fourth generation (4G) wireless services, IEEE 802.11n, IEEE 802.16, and IEEE 802.20. The basic OFDM concept includes dividing the 3.1-10.6 GHz spectrum into multiple 528 MHz bands that support data rates up to and beyond 110 Mbps.

OFDM has an inherent robustness against narrowband interference and an excellent robustness in multi-path environments based on frequency hopping techniques. In frequency hopping, the frequency synthesizer switches to a different frequency rapidly after each transmission. Frequency hopping is advantageous, for example, because a poor transmission channel can be averaged over multiple channels so that the effects of the poor transmission channel can be reduced. In existing frequency-hopping applications, as employed, for example, to support the Bluetooth protocol, the allowed switching times are defined such that conventional Phase Locked-Loop (PLL) synthesizers are adequate. However, the switching time in the newly proposed MBOFDM standard is only 9 ns as compared to the Bluetooth standard of 220 μs. The significantly shorter switching time is not supportable by conventional synthesizers.

Two solutions to support the extremely fast switching times required by the OFDM standard have been proposed by MBOA members. The first approach uses several independent synthesizers (e.g. Integer-N PLLs) running at fixed frequencies and combines them with a Radio Frequency (RF) multiplexing switch at the output. Switching from one PLL output to another performs the frequency hopping. A frequency-hopping standard with N bands requires N independent synthesizers running simultaneously. As a result, drawbacks to this concept include the large area required for the N synthesizers and the large power consumption required by the N synthesizers. Additionally, interference between the plurality of voltage controlled oscillators required becomes a critical issue when the synthesizers are located close to each other as in a single-chip solution.

The second approach uses one PLL synthesizer that generates a fixed RF frequency that is divided by frequency dividers and fed to several single-sideband (SSB) mixers. Different RF switches are used to switch different input frequencies to the SSB mixers and, by this, change the SSB mixers output frequency. A cascaded system of switches, mixers, and frequency dividers is needed to provide the required N different frequency bands. Again, the drawbacks to this concept include the large area required for the cascaded system of switches, mixers, and frequency dividers and the large power consumption required by the devices especially if more than a few frequencies are to be produced. Additionally, this concept is only applicable if the required frequencies are an integer multiple of a relatively high reference frequency as in the MBOFDM standard. However, this concept may not be valid in other standards. Yet another drawback to this concept is the reliance on high performance SSB mixers since the always existing unwanted sidebands degrade the synthesizer's output spectrum.

What is needed, therefore, is a device that supports the fast frequency switching times of the MBOFDM standard. What is further needed is a device that requires less area and uses less power while supporting the fast frequency switching times of the MBOFDM standard. What is still further needed is a device that supports other standards in addition to the MBOFDM standard.

### SUMMARY OF THE INVENTION

An exemplary embodiment of the invention relates to a frequency synthesizer for generating local oscillator frequencies. The frequency synthesizer includes a frequency controller, a multi-band oscillator, and a frequency calibrator. The frequency controller controls a center frequency for a plurality of center frequencies capable of transmission from a transmitter and selects the center frequency corresponding to a transmission center frequency from the plurality of center frequencies. The multi-band oscillator receives the selected center frequency from the frequency controller and generates a local oscillator signal having the selected center frequency. The frequency calibrator receives the local oscillator signal generated by the multi-band oscillator, defines a correction value for the center frequency of the local oscillator signal, and sends the correction value to the frequency controller.

The frequency controller includes a frequency selector and a frequency tuner. The frequency selector includes a plurality of registers and a multiplexer. Each register of the frequency selector holds a digital control word of one of the plurality of center frequencies. The multiplexer of the frequency selector receives the digital control word from one of the plurality of registers and sends the digital control word to the multi-band oscillator.

The frequency tuner includes a plurality of registers, a multiplexer, and a digital-to-analog converter. Each register of the frequency tuner holds a digital value of one of the plurality of center frequencies. The multiplexer of the frequency tuner receives the digital value from one of the plurality of registers based on the transmission center frequency. The digital-to-analog converter is configured to receive the digital value from the multiplexer of the-frequency tuner, to convert the digital value to an analog value, and to send the analog value to the multi-band oscillator.

The frequency calibrator includes a multiplexer, a plurality of counters, and logic to define the correction value using the plurality of counters. The multiplexer of the frequency calibrator receives the local oscillator signal generated by the multi-band oscillator and selectively sends the local oscillator signal to one of a plurality of counters based on the selected center frequency of the local oscillator signal. The plurality of counters count the number of oscillation periods of the local oscillator signal received from the multiplexer.

Yet another exemplary embodiment of the invention relates to an integrated circuit for generating local oscillator frequencies. The integrated circuit includes a frequency controller, a multi-band oscillator, and a frequency calibrator. The frequency controller control a center frequency for a plurality of center frequencies capable of transmission from a transmitter and selects the center frequency corresponding to a transmission center frequency from the plurality of center frequencies. The multi-band oscillator receives the selected center frequency from the frequency controller and generates a local oscillator signal having the selected center frequency. The frequency calibrator receives the local oscillator signal generated by the multi-band oscillator, defines a correction value for the center frequency of the local oscillator signal, and sends the correction value to the frequency controller.

The frequency controller includes a frequency selector and a frequency tuner. The frequency selector includes a plurality of registers and a multiplexer. Each register of the frequency selector holds a digital control word of one of the plurality of center frequencies. The multiplexer of the frequency selector receives the digital control word from one of the plurality of registers and sends the digital control word to the multi-band oscillator.

The frequency tuner includes a plurality of registers, a multiplexer, and a digital-to-analog converter. Each register of the frequency tuner holds a digital value of one of the plurality of center frequencies. The multiplexer of the frequency tuner receives the digital value from one of the plurality of registers based on the transmission center frequency. The digital-to-analog converter is configured to receive the digital value from the multiplexer of the frequency tuner, to convert the digital value to an analog value, and to send the analog value to the multi-band oscillator.

The frequency calibrator includes a multiplexer, a plurality of counters, and logic to define the correction value using the plurality of counters. The multiplexer of the frequency calibrator receives the local oscillator signal generated by the multi-band oscillator and selectively sends the local oscillator signal to one of a plurality of counters based on the selected center frequency of the local oscillator signal. The plurality of counters count the number of oscillation periods of the local oscillator signal received from the multiplexer.

Still another exemplary embodiment of the invention relates to a device for performing fast frequency hopping. The device includes a communication interface, a processor, and a frequency synthesizer. The communication interface is capable of transmitting an output signal having a transmission center frequency. The processor couples to the communication interface and selects the transmission center frequency of the output signal from a plurality of center frequencies capable of transmission from the communication interface.

The frequency synthesizer includes a frequency controller, a multi-band oscillator, and a frequency calibrator. The frequency controller controls a center frequency for the plurality of center frequencies and selects the center frequency corresponding to the selected transmission center frequency. The multi-band oscillator receives the selected center frequency from the frequency controller and generates a local oscillator signal having the selected center frequency. The frequency calibrator receives the local oscillator signal generated by the multi-band oscillator, defines a correction value for the selected center frequency of the local oscillator signal, and sends the correction value to the frequency controller.

The frequency controller includes a frequency selector and a frequency tuner. The frequency selector includes a plurality of registers and a multiplexer. Each register of the frequency selector holds a digital control word of one of the plurality of center frequencies. The multiplexer of the frequency selector receives the digital control word from one of the plurality of registers and sends the digital control word to the multi-band oscillator.

The frequency tuner includes a plurality of registers, a multiplexer, and a digital-to-analog converter. Each register of the frequency tuner holds a digital value of one of the plurality of center frequencies. The multiplexer of the frequency tuner receives the digital value from one of the plurality of registers based on the transmission center frequency. The digital-to-analog converter is configured to receive the digital value from the multiplexer of the frequency tuner, to convert the digital value to an analog value, and to send the analog value to the multi-band oscillator.

The frequency calibrator includes a multiplexer, a plurality of counters, and logic to define the correction value using the plurality of counters. The multiplexer of the frequency calibrator receives the local oscillator signal generated by the multi-band oscillator and selectively sends the local oscillator signal to one of a plurality of counters based on the selected center frequency of the local oscillator signal. The plurality of counters count the number of oscillation periods of the local oscillator signal received from the multiplexer.

Still another exemplary embodiment of the invention relates to a system for performing fast frequency hopping. The system includes a terminal and a base station in communication with the terminal. The terminal includes a communication interface, a processor, and a frequency synthesizer. The communication interface is capable of transmitting an output signal having a transmission center frequency. The processor couples to the communication interface and selects the transmission center frequency of the output signal from a plurality of center frequencies capable of transmission from the communication interface. The base station receives the output signal from the terminal.

The frequency synthesizer includes a frequency controller, a multi-band oscillator, and a frequency calibrator. The frequency controller controls a center frequency for the plurality of center frequencies and selects the center frequency corresponding to the selected transmission center frequency. The multi-band oscillator receives the selected center frequency from the frequency controller and generates a local oscillator signal having the selected center frequency. The frequency calibrator receives the local oscillator signal generated by the multi-band oscillator, defines a correction value for the selected center frequency of the local oscillator signal, and sends the correction value to the frequency controller.

The frequency controller includes a frequency selector and a frequency tuner. The frequency selector includes a plurality of registers and a multiplexer. Each register of the frequency selector holds a digital control word of one of the plurality of center frequencies. The multiplexer of the frequency selector receives the digital control word from one of the plurality of registers and sends the digital control word to the multi-band oscillator.

The frequency tuner includes a plurality of registers, a multiplexer, and a digital-to-analog converter. Each register of the frequency tuner holds a digital value of one of the plurality of center frequencies. The multiplexer of the frequency tuner receives the digital value from one of the plurality of registers based on the transmission center frequency. The digital-to-analog converter is configured to receive the digital value from the multiplexer of the frequency tuner, to convert the digital value to an analog value, and to send the analog value to the multi-band oscillator.

The frequency calibrator includes a multiplexer, a plurality of counters, and logic to define the correction value using the plurality of counters. The multiplexer of the frequency calibrator receives the local oscillator signal generated by the multi-band oscillator and selectively sends the local oscillator signal to one of a plurality of counters based on the selected center frequency of the local oscillator signal. The plurality of counters count the number of oscillation periods of the local oscillator signal received from the multiplexer.

Still another exemplary embodiment of the invention relates to a method of performing fast frequency hopping. The method includes selecting a center frequency for transmission of an output signal from a plurality of center frequencies, receiving the selected center frequency at a multi-band oscillator, generating a local oscillator signal at the selected center frequency using the multi-band oscillator, receiving the local oscillator signal at a frequency calibrator, selecting a counter from a plurality of counters using the selected center frequency of the local oscillator signal, and incrementing the selected counter for each oscillation period of the local oscillator signal.

The method may further comprise, at the end of a time interval, calculating an actual center frequency for each of the plurality of center frequencies, comparing the calculated actual center frequency to the center frequency of each of the plurality of center frequencies, calculating a correction value for each of the plurality of center frequencies using the comparison, and correcting the center frequency of each of the plurality of center frequencies using the correction value. Selecting a center frequency for transmission may include performing frequency selection using a digital control word and performing frequency selection using a digital to analog converter.

Still another exemplary embodiment of the invention relates to a computer program product for performing fast frequency hopping. The computer program product includes computer code configured to select a center frequency for transmission of an output signal from a plurality of center frequencies, receive the selected center frequency at a multi-band oscillator, generating a local oscillator signal at the selected center frequency using the multi-band oscillator, receive the local oscillator signal at a frequency calibrator, select a counter from a plurality of counters using the selected center frequency of the local oscillator signal, and increment the selected counter for each oscillation period of the local oscillator signal.

The computer code may further be configured to, at the end of a time interval, calculate an actual center frequency for each of the plurality of center frequencies, compare the calculated actual center frequency to the center frequency of each of the plurality of center frequencies, calculate a correction value for each of the plurality of center frequencies using the comparison, and correct the center frequency of each of the plurality of center frequencies using the correction value. Selecting a center frequency for transmission may include performing frequency selection using a digital control word and performing frequency selection using a digital to analog converter.

Other principal features and advantages of the invention will become apparent to those skilled in the art upon review of the following drawings, the detailed description, and the appended claims.

### BRIEF DESCRIPTION OF THE DRAWINGS

The exemplary embodiments will hereafter be described with reference to the accompanying drawings, wherein like numerals will denote like elements.

FIG. 1 is an overview diagram of a frequency hopping technique in accordance with an exemplary embodiment.

FIG. 2 is a block diagram of a frequency synthesizer in accordance with an exemplary embodiment.

FIG. 3 is a detailed block diagram of a frequency synthesizer in accordance with an exemplary embodiment.

FIG. 4 is an overview diagram of a terminal in accordance with an exemplary embodiment.

FIG. 5 is an overview diagram of a system in accordance with an exemplary embodiment.

FIG. 6 is a flow diagram depicting operations at a terminal in accordance with an exemplary embodiment.

### DETAILED DESCRIPTION OF THE PREFERRED EMBODIMENTS

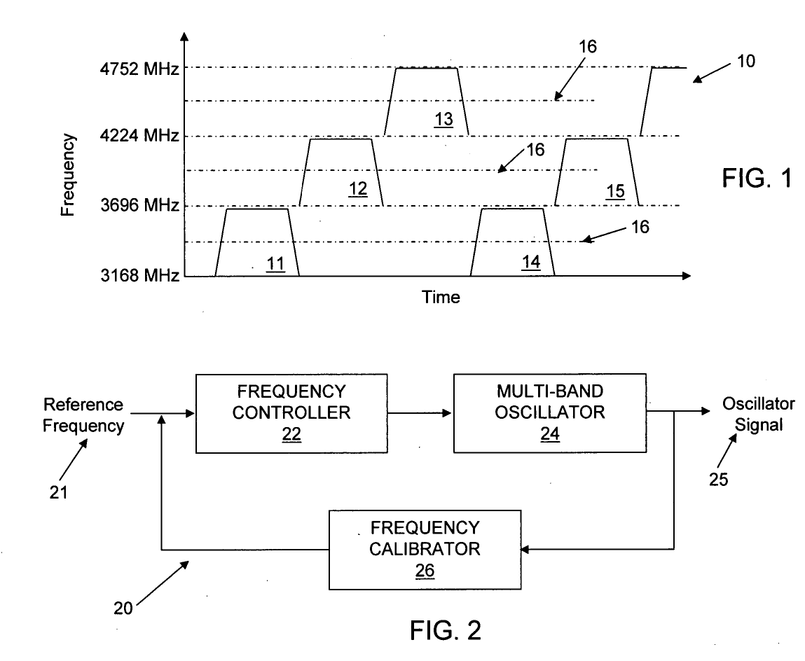

OFDM has an inherent robustness against narrowband interference and an excellent robustness in multi-path environments based on frequency hopping techniques. In frequency hopping, the frequency synthesizer switches to a different frequency rapidly after each transmission. For example, FIG. 1 illustrates an example frequency hopping scheme 10. A series of signals 11, 12, 13, 14, 15, etc. repeat in a sequence using three different center frequencies 16. The example center frequencies shown in FIG. 1 are 3432 MHz, 3960 MHz, and 4488 MHz. The significantly shorter switching time of 9.5 ns required in the OFDM standard, however, is not supportable by conventional-synthesizers. Current proposals to achieve the faster switching time consume a large area and a large amount of power. Exemplary embodiments described herein provide a system, terminal, integrated circuit, frequency synthesizer, computer program product, and method to support the fast switching time required by the OFDM standard using less area and less power.

A frequency synthesizer is an electronic system for generating any of a range of frequencies. With reference to FIG. 2, a frequency synthesizer 20 is shown. The frequency synthesizer 20 includes a frequency controller 22, a multi-band oscillator 24, and a frequency calibrator 26. A reference frequency is received by the frequency controller 22. In an exemplary embodiment, the reference frequency may be 32 MHz. In conventional frequency synthesizers based on the integer-N PLL principle, the frequency of the oscillator signal must be an integer multiple of the reference frequency 21. The frequency synthesizer 20, however, may output an oscillator signal 25 that is not an integer multiple of the reference frequency 21 because the number of voltage control oscillator (VCO) periods is accumulated over a great number of reference periods. The “averaging over multiple reference periods” may be done in the digital domain by the frequency calibration logic. In fractional-N PLLs, the averaging is done by the analog low-pass filter that is connected to the phase-detector and charge pump. The cut-off frequency of the analog low-pass filter limits the switching speed of fractional-N PLLs, making them unable to switch, for example, within nine nanoseconds from one channel to the next. The frequency controller 22 controls a plurality of center frequencies 16 that are capable of transmission from a transmitter. The frequency controller 22 selects a center frequency from the plurality of center frequencies.

An electronic oscillator produces a repetitive electronic signal, often a sine wave or a square wave at a specified center frequency. The multi-band oscillator 24 is capable of generating repetitive electronic signals at multiple different center frequencies as requested. The multi-band oscillator 24 generates the local oscillator (LO) signal 25 that is needed for frequency translation in the radio front-end of a wireless data transmission system. The RF front-end is the interface between the antenna and the digital baseband processing unit. The multi-band oscillator 24 receives the selected center frequency from the frequency controller 22 and generates a LO signal 25 having the selected center frequency.

The frequency calibrator 26 corrects a calculated center frequency of the oscillator signal to match the center frequency selected for transmission. The corrected center frequency is then input to the frequency controller 22 for use in future transmissions. In most modern wireless transmission standards, the LO frequency of the transmitter and of the receiver must match with only a finite accuracy. For example, the MBOFDM standard requires that the frequencies match with an accuracy of 400 kHz. As a result, some error in the oscillator signal center frequency as compared to the center frequency selected may be tolerated.

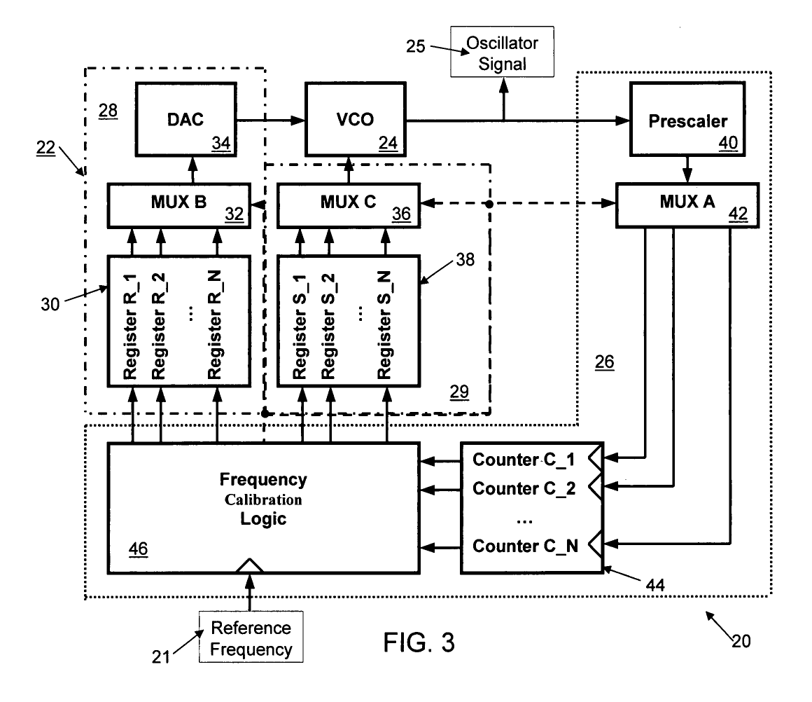

FIG. 3 shows a more detailed diagram of the frequency synthesizer 20 that includes the frequency controller 22, the multi-band oscillator 24, and the frequency calibrator 26. The multi-band oscillator 24 may be implemented using a VCO that generates the LO signal 25. In an exemplary embodiment, the tuning slope of the VCO is approximately 100 MHz/V. The multi-band oscillator 24 may achieve band selection using switched MOS capacitor arrays and fine tuning using MOS varactors or varactor diodes. Thus, the frequency controller 22 may include a frequency selector 29 for band selection and a frequency tuner 28 for fine tuning of the frequency selection.

The frequency selector 29 provides coarse frequency selection and includes a plurality of registers 38 and a multiplexer 36. The number of registers corresponds to the number of center frequencies supported by the frequency synthesizer 20. For example, using the frequency hopping scheme of FIG. 1, three frequencies are required. As a result, in a system employing the three frequency scheme of FIG. 1, the frequency selector includes three registers 38. Each register of the frequency selector 29 holds a digital control word of one of the plurality of center frequencies. Using the three frequency hopping scheme of FIG. 1, the digital control word may be two bits in length allowing representation of four different frequency stages. The multiplexer 36 receives the digital control word from one of the plurality of registers 38 and sends the digital control word to the multi-band oscillator 24. Coarse tuning of the multi-band oscillator 24 is provided through the two bit digital control word by switching in additional capacitance of the multi-band oscillator 24.

The frequency tuner 28 provides fine frequency tuning using an analog tuning voltage. The frequency tuner 28 includes a plurality of registers 30, a multiplexer 32, and a digital-to-analog converter (DAC) 34. In contrast to a conventional PLL synthesizer, the analog tuning voltage of the frequency synthesizer 20 is provided by the DAC 34 instead of an analog loop filter. By using the DAC 34, the frequency synthesizer 20 can achieve the required fast switching times. The settling time of the DAC 34 may be as low as a few nanoseconds. In contrast, traditional integer-N or fractional-N PLLs derive the analog tuning voltage for the VCO from the output of an analog low-pass filter. The step response of the analog low-pass filter is usually in the range of microseconds or milliseconds (depending on the used reference frequency). As a result, hopping from one channel to the next within a few nanoseconds, as required in the MBOFDM standard, is virtually impossible. Again, the number of registers 32 corresponds to the number of center frequencies supported by the frequency synthesizer 20. Each register of the frequency tuner holds a digital value of one of the plurality of center frequencies for input to the DAC 34. The multiplexer 32 receives the digital value from one of the plurality of registers 30 based on the transmission center frequency. In an exemplary embodiment, each register is ten bits in length. The DAC 34 is configured to receive the digital value from the multiplexer 32. As a result, in an exemplary embodiment, the DAC 34 accepts a ten bit input.

The DAC 34 converts the received digital value to an analog value. The analog value produced by the DAC 34 is sent to the multi-band oscillator 24 that creates the LO signal 25 at the center frequency. In an exemplary embodiment, the DAC 34 supports a 3.2 M samples/sec sampling rate and has a settling time of less than or equal to five nanoseconds. The DAC may be implemented as a resistor-string DAC with medium resolution. The differential non-linearity and integral non-linearity of the DAC are of minor importance to the frequency synthesizer design because the DAC is implemented as part of the synthesizer's calibration loop. As a result, no frequency error resulting from a non-linearity in the DAC is produced at the synthesizer output. The DAC resolution depends on the sensitivity of the multi-band oscillator 24 and the allowed static frequency error of the transmission standard. Because sensitivity is a design variable in multi-band oscillators, the multi-band oscillator can be matched to a medium resolution DAC as known to those skilled in the art.

The frequency calibrator 26 includes a prescaler 40, a multiplexer 42, a plurality of counters 44, and a logic 46. The prescaler 40 divides the LO signal frequency by a fixed division ratio. The higher the division ratio, the lower the operating frequency of the counters 44. The lower the operating frequency of the counters 44, the simpler the counters 44 are to implement because the number of bits required for each counter is reduced. The number of bits is reduced for each counter because the counters are counting the number of oscillation periods in the input signal. However, to achieve the same frequency resolution as the division ratio increases (thereby reducing the counter bit size), a greater time interval is needed for accumulating the count in the counters 44. The frequency calibrator 26 may not include a prescaler 40.

The multiplexer 42 receives the LO signal 25 generated by the multi-band oscillator 24 or, optionally, the lower frequency signal from the prescaler 40 and selectively sends the signal to one of a plurality of counters 44 based on the center frequency of the signal. The plurality of counters 44 count the number of oscillation periods of the signal received from the multiplexer 42. In an exemplary embodiment, the counters 44 are each 20 bits in length to achieve the frequency accuracy (considering frequency error) for the MBOFDM standard. In general, the greater the allowed frequency error, the lower the required bit-length of the counters 44. To minimize the power consumption of the counters 44, the counters 44 may be implemented as asynchronous circuits. Access issues to the asynchronous counters present no design issues because the logic 46 evaluates the counter value only when the counter is not counting. Only one counter is active at a time.

The logic 46 defines the correction value using the plurality of counters 44. In an exemplary embodiment, the logic 46 uses only digital components. The number of oscillation periods during a fixed time interval is captured in the counters 44. The logic 46 calculates the actual center frequency of the LO signal 25. The time interval determines the accuracy of the calculation. In a fast-hopping system, the LO signal 25 remains on one frequency for only a short time interval. This time interval is generally too short to achieve the needed resolution. To overcome this limitation, the oscillation period count is extended over a number of frequency hops. As a result, the number of counters 44 also corresponds to the number of center frequencies supported by the frequency synthesizer 20 because a count is maintained independently for each center frequency. After accumulating the count of LO signal 25 oscillation periods over a number of hops, the logic 46 determines the deviation of each of the center frequencies from their ideal, expected values. A correction value is calculated for each center frequency and corrected digital values for the frequencies are multiplexed to the registers 30. Using this method, the synthesizer 20 tracks and permanently corrects any changes in the LO signal 25 frequency for example due to temperature or supply voltage variation.

The synthesizer 20 can be implemented as an integrated circuit on a single chip. The logic 46, the multiplexers 32, 36, 42, and the registers 30, 38 may be implemented using standard CMOS logic.

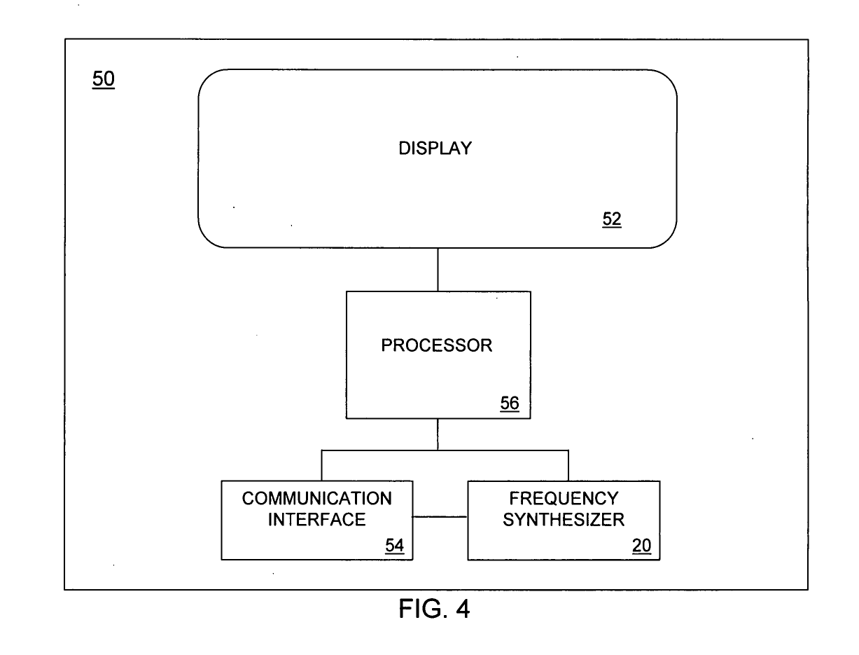

In an exemplary embodiment, a terminal 50, as shown in FIG. 4, comprises a display 52, a communication interface 54, a processor 56, and the frequency synthesizer 20. The term “terminal” should be understood to include, without limitation, cellular telephones, Personal Data Assistants (PDAs), such as those manufactured by PALM, Inc., Instant Messaging Devices (IMD), such as those manufactured by Blackberry, Inc., and other hand-held devices; notebook computers; laptop computers; desktop computers; mainframe computers; multi-processor systems; etc. A terminal may or may not be mobile. The exact architecture of the terminal 52 is not important. Different and additional terminal compatible devices may be incorporated into the terminal 50.

The display 52 of the terminal 50 is optional. The display 52 presents information to a user. The display 52 may be a thin film transistor (TFT) display, a light emitting diode (LED) display, a Liquid Crystal Display (LCD), or any of a variety of different displays known to those skilled in the art. The processor 56 executes instructions that cause the terminal 50 to behave in a predetermined manner. The instructions may be written using one or more programming languages, scripting languages, assembly languages, etc. Additionally, the instructions may be carried out by a special purpose computer, logic circuits, or hardware circuits. Thus, the processor 56 may be implemented in hardware, firmware, software, or any combination of these methods. The processor 56 may includes instructions that select the transmission center frequency input to the frequency synthesizer, for example, using a system clock and sequentially cycling through the plurality of center frequencies.

The communication interface 54 provides an interface for receiving and transmitting calls, messages, and any other information communicated across a network. Communications between the terminal 50 and the network may be through one or more of the following connection methods, without limitation: an infrared communications link, a wireless communications link, a cellular network link, a physical serial connection, a physical parallel connection, a link established according to the Transmission Control Protocol/Internet Protocol and Standards (TCP/IP), etc. Transferring content to and from the terminal may use one or more of these connection methods. The communication interface 54 is capable of transmitting an output signal having the transmission center frequency selected from the plurality of center frequencies.

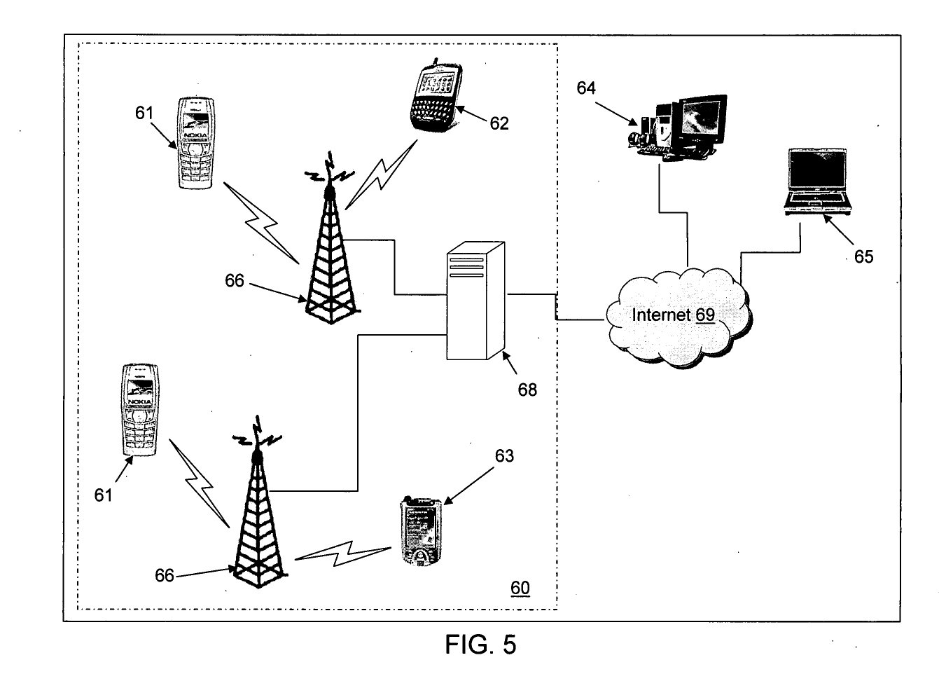

With reference to FIG. 5, the system 60 comprises terminals, base stations 66, and a network server 68. The terminals may include a cellular telephone 61, an IMD 62, a PDA 63, and the like. In the system 60, the terminals may send and receive signals through the base station 66. The network server 68 allows communication between the terminals and a broader network. For example, the network server 68 may connect the terminals with other terminals through the Internet 69. Other terminals may include, but are not limited to, a desktop 64, a laptop 65, the cellular telephone 61, the IMD 62, and the PDA 63.

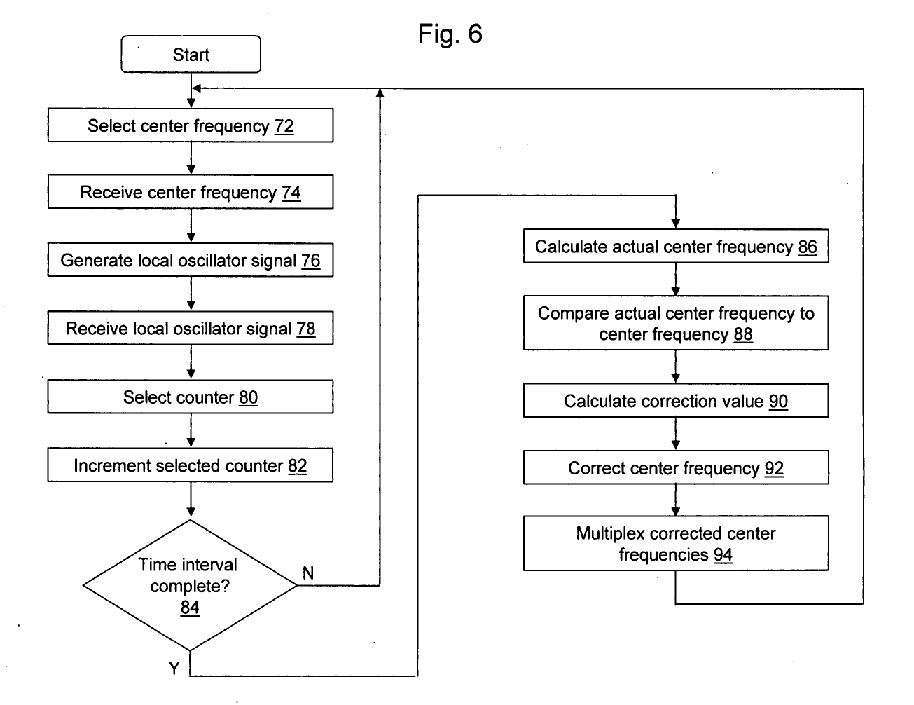

FIG. 6 describes the method for performing fast frequency hopping. At operation 72, a center frequency for transmission of an output signal is selected from a plurality of center frequencies. The selected center frequency is received at the multi-band oscillator 24 at operation 74. The multi-band oscillator 24 generates the LO signal 25 at operation 76. As part of a calibration loop, the LO signal 25 is received at the frequency calibrator 26 at operation 78. The frequency of the LO signal 25 may be reduced by a prescaler 40 as related previously. At operation 80, the multiplexer 42 of the frequency calibrator 26 selects the counter from the plurality of counters 44 to receive the LO signal 25 (optionally reduced in frequency by the prescaler 40) based on the center frequency of the LO signal 25. At operation 82, the selected counter is incremented for each oscillation period counted for the received LO signal 25. However, in alternative embodiments wherein the prescaler 40 is used, the selected counter may not be incremented for each oscillation period. For example, in an embodiment wherein the prescaler 40 has a prescaler ratio equal to eight, the selected counter may be incremented only once after eight oscillation periods.

The logic 46 determines if the appropriate time interval for accumulating the oscillation period count has been completed at operation 84. If the time interval has not been completed, processing continues at operation 72. If the time interval has been completed, the logic 46 calculates the actual center frequency for each of the plurality of frequencies based on the counter values at operation 86. Dividing the value of each counter by the time interval that each frequency was transmitted provides an estimation of the actual center frequency. The logic 46 compares the calculated actual center frequency to the ideal or expected frequency for each of the plurality of frequencies at operation 88. At operation 90, the logic 46 calculates a correction value for each of the plurality of frequencies based on the comparison. The logic 46 corrects each of the plurality of frequencies at operation 92. The correct frequencies are multiplexed to the register 30 of the frequency tuner 22. Processing continues at operation 72 with calibrated center frequencies.

The exemplary embodiments described provide the following advantages over conventional and proposed systems:
Less power consumption and less silicon area is needed.
Only one oscillator and one prescaler are needed independent of the number of center frequencies.
No loop filters are required.
No SSB mixers are required eliminating any sideband rejection problem.
There is no restriction to an integer multiple of the reference frequency so that arbitrary frequencies can be generated to support different standards.
The additional hardware to support additional frequencies is low making the system easily scalable.

It is understood that the invention is not confined to the particular embodiments set forth herein as illustrative, but embraces all such modifications, combinations, and permutations as come within the scope of the following claims. Thus, the description of the exemplary embodiments is for purposes of illustration and not limitation.

What is claimed is:

1. A frequency synthesizer for generating local oscillator frequencies, the synthesizer comprising:
a frequency controller, wherein the frequency controller is configured to:
control a center frequency for a plurality of center frequencies capable of transmission from a transmitter; and
select the center frequency corresponding to a transmission center frequency from the plurality of center frequencies;
a multi-band oscillator, wherein the multi-band oscillator is configured to:
receive the selected center frequency from the frequency controller; and
generate a local oscillator signal having the selected center frequency; and
a frequency calibrator, wherein the frequency calibrator is configured to:
receive the local oscillator signal generated by the multi-band oscillator;
define a correction value for the selected center frequency of the local oscillator signal; and
send the correction value to the frequency controller.

2. The synthesizer of claim 1, wherein the frequency calibrator comprises:
a multiplexer, wherein the multiplexer is configured to:
receive the local oscillator signal generated by the multi-band oscillator; and
selectively send the local oscillator signal to one of a plurality of counters based on the selected center frequency of the local oscillator signal;
the plurality of counters, wherein the plurality of counters count the number of oscillation periods of the local oscillator signal received from the multiplexer; and
logic to define the correction value using the plurality of counters.

3. The synthesizer of claim 1, wherein the frequency controller comprises:
a frequency selector; and
a frequency tuner.

4. The synthesizer of claim 3, wherein the frequency tuner comprises:
a plurality of registers, wherein each register holds a digital value of one of the plurality of center frequencies;
a multiplexer, wherein the multiplexer receives the digital value from one of the plurality of registers based on the transmission center frequency; and
a digital-to-analog converter, wherein the digital-to-analog converter is configured to:
receive the digital value from the multiplexer;
convert the digital value to an analog value; and
send the analog value to the multi-band oscillator.

5. The synthesizer of claim 3, wherein the frequency selector comprises:
a plurality of registers, wherein each register holds a digital control word of one of the plurality of center frequencies; and
a multiplexer, wherein the multiplexer receives the digital control word from one of the plurality of registers and sends the digital control word to the multi-band oscillator.

6. An integrated circuit for generating local oscillator frequencies, the synthesizer comprising:
a frequency controller, wherein the frequency controller is configured to:
control a center frequency for a plurality of center frequencies capable of transmission from a transmitter; and
select the center frequency corresponding to a transmission center frequency from the plurality of center frequencies;
a multi-band oscillator, wherein the multi-band oscillator is configured to:
receive the selected center frequency from the frequency controller; and
generate a local oscillator signal having the selected center frequency; and
a frequency calibrator, wherein the frequency calibrator is configured to:
receive the local oscillator signal generated by the multi-band oscillator;
define a correction value for the selected center frequency of the local oscillator signal; and
send the correction value to the frequency controller.

7. The integrated circuit of claim 6, wherein the frequency calibrator comprises:
a multiplexer, wherein the multiplexer is configured to:
receive the local oscillator signal generated by the multi-band oscillator; and
selectively send the local oscillator signal to one of a plurality of counters based on the selected center frequency of the local oscillator signal;
the plurality of counters, wherein the plurality of counters count the number of oscillation periods of the local oscillator signal received from the multiplexer; and
logic to define the correction value using the plurality of counters.

8. The integrated circuit of claim 6, wherein the frequency controller comprises:
a frequency selector; and
a frequency tuner.

9. The integrated circuit of claim 8, wherein the frequency tuner comprises:
a plurality of registers, wherein each register holds a digital value of one of the plurality of center frequencies;
a multiplexer, wherein the multiplexer receives the digital value from one of the plurality of registers based on the transmission center frequency; and
a digital-to-analog converter, wherein the digital-to-analog converter is configured to:
receive the digital value from the multiplexer;
convert the digital value to an analog value; and
send the analog value to the multi-band oscillator.

10. The integrated circuit of claim 8, wherein the frequency selector comprises:
a plurality of registers, wherein each register holds a digital control word of one of the plurality of center frequencies; and
a multiplexer, wherein the multiplexer receives the digital control word from one of the plurality of registers and sends the digital control word to the multi-band oscillator.

11. A device for performing fast frequency hopping, the device comprising:
a communication interface capable of transmitting an output signal having a transmission center frequency;
a processor, wherein the processor is coupled to the communication interface and selects the transmission center frequency of the output signal from a plurality of center frequencies capable of transmission from the communication interface; and
a frequency synthesizer, wherein the frequency synthesizer comprises:
a frequency controller, wherein the frequency controller is configured to:
control a center frequency for the plurality of center frequencies; and
select the center frequency corresponding to the selected transmission center frequency;
a multi-band oscillator, wherein the multi-band oscillator is configured to:
receive the selected center frequency from the frequency controller; and
generate a local oscillator signal having the selected center frequency; and
a frequency calibrator, wherein the frequency calibrator is configured to:
receive the local oscillator signal generated by the multi-band oscillator;
define a correction value for the selected center frequency of the local oscillator signal; and
send the correction value to the frequency controller.

12. The device of claim 1 1, wherein the frequency calibrator of the frequency synthesizer comprises:
a multiplexer, wherein the multiplexer is configured to:
receive the local oscillator signal generated by the multi-band oscillator; and
selectively send the local oscillator signal to one of a plurality of counters based on the selected center frequency of the local oscillator signal;
the plurality of counters, wherein the plurality of counters count the number of oscillation periods of the local oscillator signal received from the multiplexer; and
logic to define the correction value using the plurality of counters.

13. The device of claim 11, wherein the frequency controller of the frequency synthesizer comprises:
a frequency selector; and
a frequency tuner.

14. The device of claim 13, wherein the frequency tuner of the frequency controller comprises:
a plurality of registers, wherein each register holds a digital value of one of the plurality of center frequencies;
a multiplexer, wherein the multiplexer receives the digital value from one of the plurality of registers based on the transmission center frequency; and
a digital-to-analog converter, wherein the digital-to-analog converter is configured to:
receive the digital value from the multiplexer;
convert the digital value to an analog value; and
send the analog value to the multi-band oscillator.

15. The device of claim 13, wherein the frequency selector of the frequency controller comprises:
a plurality of registers, wherein each register holds a digital control word of one of the plurality of center frequencies; and
a multiplexer, wherein the multiplexer receives the digital control word from one of the plurality of registers and sends the digital control word to the multi-band oscillator.

16. A system for performing fast frequency hopping, the system comprising:
a terminal, the terminal comprising:
a communication interface capable of transmitting an output signal having a transmission center frequency;
a processor, wherein the processor is coupled to the communication interface and selects the transmission center frequency of the output signal from a plurality of center frequencies capable of transmission from the communication interface; and
a frequency synthesizer, wherein the frequency synthesizer comprises:
a frequency controller, wherein the frequency controller is configured to:
control a center frequency for the plurality of center frequencies; and
select the center frequency corresponding to the selected transmission center frequency;
a multi-band oscillator, wherein the multi-band oscillator is configured to:
receive the selected center frequency from the frequency controller; and
generate a local oscillator signal having the selected center frequency; and
a frequency calibrator, wherein the frequency calibrator is configured to:
receive the local oscillator signal generated by the multi-band oscillator;
define a correction value for the selected center frequency of the local oscillator signal; and
send the correction value to the frequency controller; and
a base station in communication with the terminal, wherein the base station receives the output signal from the terminal.

17. The system of claim 16, wherein the frequency calibrator of the frequency synthesizer comprises:
a multiplexer, wherein the multiplexer is configured to:
receive the local oscillator signal generated by the multi-band oscillator; and
selectively send the local oscillator signal to one of a plurality of counters based on the selected center frequency of the local oscillator signal;
the plurality of counters, wherein the plurality of counters count the number of oscillation periods of the local oscillator signal received from the multiplexer; and
logic to define the correction value using the plurality of counters.

18. The system of claim 16, wherein the frequency controller of the frequency synthesizer comprises:
a frequency selector; and
a frequency tuner.

19. The system of claim 18, wherein the frequency tuner of the frequency controller comprises:
a plurality of registers, wherein each register holds a digital value of one of the plurality of center frequencies;
a multiplexer, wherein the multiplexer receives the digital value from one of the plurality of registers based on the transmission center frequency; and
a digital-to-analog converter, wherein the digital-to-analog converter is configured to:
receive the digital value from the multiplexer;
convert the digital value to an analog value; and
send the analog value to the multi-band oscillator.

20. The system of claim 18, wherein the frequency selector of the frequency controller comprises:
a plurality of registers, wherein each register holds a digital control word of one of the plurality of center frequencies; and
a multiplexer, wherein the multiplexer receives the digital control word from one of the plurality of registers and sends the digital control word to the multi-band oscillator.

21. A method of performing fast frequency hopping, the method comprising:
selecting a center frequency for transmission of an output signal from a plurality of center frequencies;
receiving the selected center frequency at a multi-band oscillator;
generating a local oscillator signal at the selected center frequency using the multi-band oscillator;
receiving the local oscillator signal at a frequency calibrator;
selecting a counter from a plurality of counters using the selected center frequency of the local oscillator signal; and
incrementing the selected counter for each oscillation period of the local oscillator signal.

22. The method of claim 21, the method further comprising:
at the end of a time interval, calculating an actual center frequency for each of the plurality of center frequencies;
comparing the calculated actual center frequency to the center frequency of each of the plurality of center frequencies;
calculating a correction value for each of the plurality of center frequencies using the comparison; and
correcting the center frequency of each of the plurality of center frequencies using the correction value.

23. The method of claim 21, wherein selecting a center frequency for transmission comprises:
performing frequency selection using a digital control word; and
performing frequency selection using a digital to analog converter.

24. A computer program product for performing fast frequency hopping, the computer program product comprising:
computer code configured to:
select a center frequency for transmission of an output signal from a plurality of center frequencies;
send the selected center frequency to a multi-band oscillator;
receive a local oscillator signal generated by a multi-band oscillator;
select a counter from a plurality of counters using the selected center frequency of the local oscillator signal; and
increment the selected counter for each oscillation period of the local oscillator signal.

25. The computer program product of claim 24, the computer code further configured to:
at the end of a time interval, calculate an actual center frequency for each of the plurality of center frequencies;
compare the calculated actual center frequency to the center frequency of each of the plurality of center frequencies;
calculate a correction value for each of the plurality of center frequencies using the comparison; and
correct the center frequency of each of the plurality of center frequencies using the correction value.

26. The computer program product of claim 24, wherein the selection of a center frequency for transmission comprises:
frequency selection using a digital control word; and
frequency selection using a digital to analog converter.
